(19) United States
(12) Patent Application Publication
(10) Pub. No.: US 2005/0076275 A1
(43) Pub. Date: Apr. 7, 2005

(54) Integraged circuit and method for testing the integrated circuit

(76) Inventors: Cornelis Hermanus Van Berkel, Eindhoven (NL); Adrianus Marinus Gerardus Peeters, Eindhoven (NL)

Correspondence Address: Philips Electronics North America Corporation;Intellectual Property & Standards, M S 41 SJ, 1109 McKay Drive, San Jose, CA, 95131, US

(21) Appl. No.: 10/480,750

(22) PCT Filed: Jun. 10, 2002
(86) PCT No.: PCT/IB02/02206

(30) Foreign Application Priority Data
Jun. 12, 2001 (EP) 01202253.9

(51) Int. Cl. G01R 31/28

(52) U.S. Cl. 714/724

(57) ABSTRACT

An integrated circuit according to the invention comprises a plurality of units (C1, C2, C3, C4;1), having first inputs (2a, 2b, 2c) for receiving control signals (n,s,t) for setting an operational mode of the unit (1). The units (1) have a functional mode, a scan in mode, a scan out mode. In the functional mode (n=1,s=0,t=1) a logical operation is performed at signals (a,b) received at one or more second inputs (4a, 4b). The result of the logical operation is provided via an internal node (6) to an output (10). In the scan in mode (n=0,s=1,t=0) a value at a scan input is stored at the internal node (6). In the scan out mode (n=0,s=0,t=1) the value at the internal node (6) is provided to the output (10). The integrated circuit according to the invention further has an evaluate mode (n=1,s=0,t=0) in which the result of the logical operation at the input signals (a,b) is stored at the internal node (6), and in which the output (10) of the units is disabled.

Integrated circuit comprising a plurality of units, having first inputs for receiving control signals for setting an operational mode of the unit, the unit having a functional mode, a scan in mode, and a scan out mode, in which functional mode a logical operation is performed at signals received at one or more second inputs, the result of the logical operation being provided via an internal node to an output, in which scan in mode a value at a scan input is stored at the internal node, in which scan out mode the value at the internal node is provided to the output.

Asynchronous circuits offer large advantages over synchronous circuits. Some of the advantages are design flexibility, the absence of clock skew, the potential for lower power consumption and performance at the average speed rate rather than at the worst case. The logical operations to be performed in those circuits may be combinational operations, such as AND, OR, but may otherwise be sequential operations, e.g. latch operations.

However, asynchronous circuits are more difficult to test than synchronous circuits.

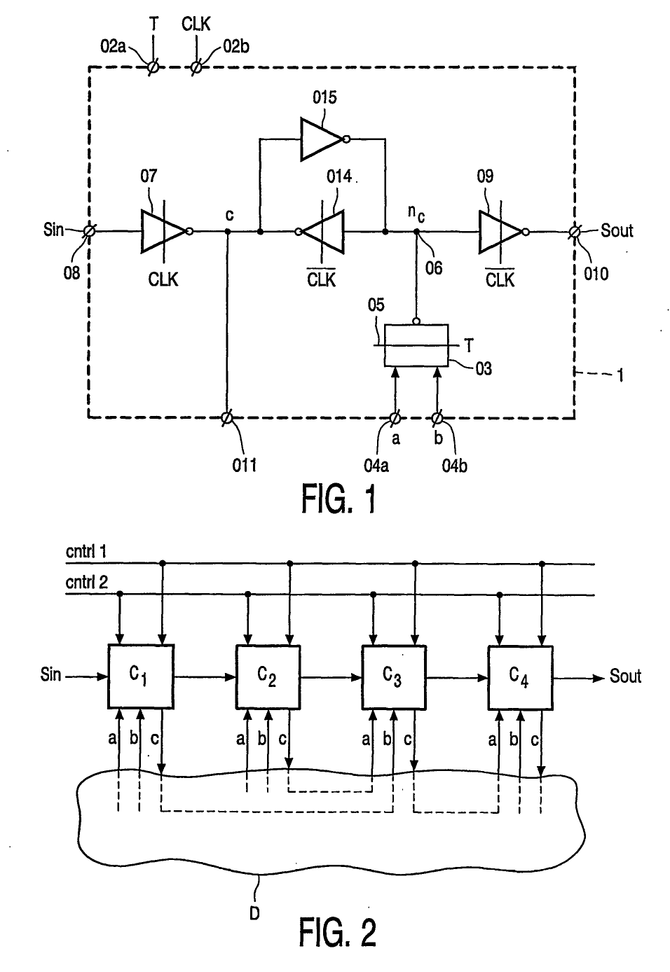

A method for testing asynchronous circuits is described in O. Petlin and S. Furber, “Designing C-elements for Testability”, Technical Report UMCS-95-10-2. FIG. 10 at page 21 thereof shows a symmetric C-element implemented in the form of a series connection of transistors. The C-element is pseudo-static in that its output, forming an internal node nc, provides an input for an inverting buffer, a functional output c whereof is weakly coupled back to the internal node nc via a inverting feedback buffer. The pseudo-static C-element 03 is part of a scan testable unit, which is schematically shown in FIG. 1. For that purpose the C-element 03 is controllable between a disabled and an enabled state by means of a signal T. The inverting buffer 014 between the internal node nc and the functional output c is made controllable between an enabled state and a disabled state by means of a signal \overline{Clk}. Also the internal node nc is coupled via a tristate inverting buffer 09 to a test output Sout. The latter inverter is also enabled/disabled by means of the signal \overline{Clk}.

Furthermore a test input 08 is coupled via a tristate inverting buffer 07 to the functional output c. This inverting buffer 07 is controllable by means of a test signal Clk. The unit 01 has a functional mode, or normal operation mode in which the circuit performs according to the specification of the C-element 03. In this mode the signals T,Clk have a value 0,0 respectively. The C-element 03 then is enabled. Also the tristate inverting buffers 014 and 09 which provide the output signals for the functional output c and the test output Sout are enabled then. The tristate inverting buffer 07 which couples the test input to the output c is disabled in the normal mode. In scan in mode the signals T and Clk have a value 1,1 a test value at input 08 is loaded to functional output c, and, in inverted form, via the inverting feedback buffer 015 to the internal node nc. In scan out mode the value of T remains 1, and the value of Clk is set to 0. Now the inverting buffer 09 at the test output 010 is enabled, so that the test value becomes available at the test output 010, and can be loaded into the next circuit forming part of a test chain.

When the C-element 03 of a unit in the chain has to be tested, a testvalue at the functional output of a previous circuit has to be enabled by setting the signal Clk to 0. At the same time the C-element 03 has to be enabled, by setting the signal T to 0. This has the disadvantage however that the element which is functionally coupled to that unit can not be tested independently.

This is clarified by means of FIG. 2, showing an integrated circuit comprising four units C1, C2, C3, C4 which are coupled to each other so as to form a chain. Apart therefrom the C-elements are also functionally coupled. The functional coupling may comprise logic circuitry D. In the example shown in FIG. 2 the functional output c of the first unit C1 is functionally coupled to the input b of the third unit C3 in the chain, and the functional output c of the second unit C2 is coupled to the input a of the third unit C3. In functional mode the units C1, . . . C4 and the logic circuitry D operate asynchronously. If it is now presumed that the logic units C1, . . . , C4 are implemented by the circuits as described above with reference to FIG. 1, and the control signals cntrl1 and cntrl2 are the signals T and Clk, then the test procedure should be as follows. First a testvector is loaded in the chain C1, . . . , C4, by setting the signal T to 1, and by alternating the signal Clk between a value 0 and 1. In order to evaluate the C-function for the testvector the value of T is set to 0 and the value of Clk is set to 0. Now, for example the response of element C3 to its inputs a and b is calculated. The response will become available at the internal node nc after a certain delay also at the functional output 011. At that moment the respons overwrites the value of the testvector loaded in the node c. In order to prevent that this happens, the tristate means 05 for the of the C-element 03 must be disabled shortly after the unit has assumed the evaluation mode. This requires an accurate timing, which is difficult to achieve.

It is a purpose of the invention to provide an integrated circuit according to the introductory paragraph in which the units of the scan chain can be of a relatively simple structure and can be reliably tested. According to this purpose the integrated circuit of the invention is characterized in that the integrated circuit further has an evaluate mode in which the result of the logical operation at the input signals is stored at the internal node, and in which the output of the units is disabled. The evaluate mode in the integrated circuit according to the invention makes it possible to evaluate the response of the logic element of the unit, without overwriting the scan-value loaded in the unit. Preferably the result of the evaluation is dynamically stored, so that the units of the scan chain can be of a simple structure.

An embodiment of the integrated circuit according to the invention is characterized in that the units have a logic circuitry for performing a logical operation at the signals received at the second inputs, first tristate means for coupling an output of the logic circuitry to the internal node in dependence of a first control signal, second tristate means for coupling the scan input to the internal node in dependence of a second control signal and third tristate means for coupling the internal node to the output, in dependence of a third control signal. The tristate means enables a simple switching between the different modes. The tristate means may be implemented in different ways, e.g. by inverting buffers or by transmission- or pass gates.

These and other aspects of the invention are described in more detail with reference to the drawing. Therein:

FIG. 1 shows a scanable unit as described in the prior art,

FIG. 2 shows an integrated circuit comprising a plurality of units,

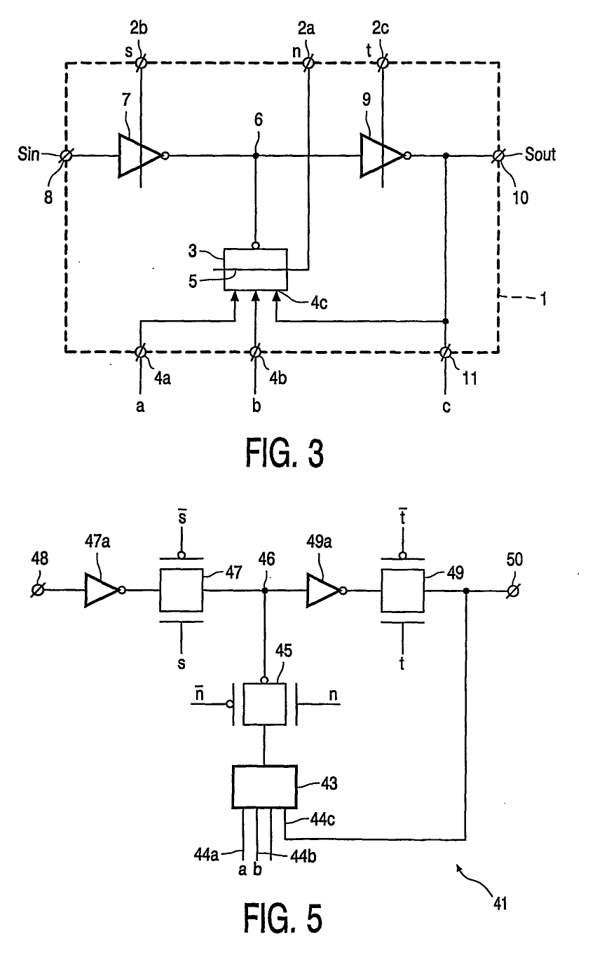

FIG. 3 shows a unit of an integrated circuit according to the invention,

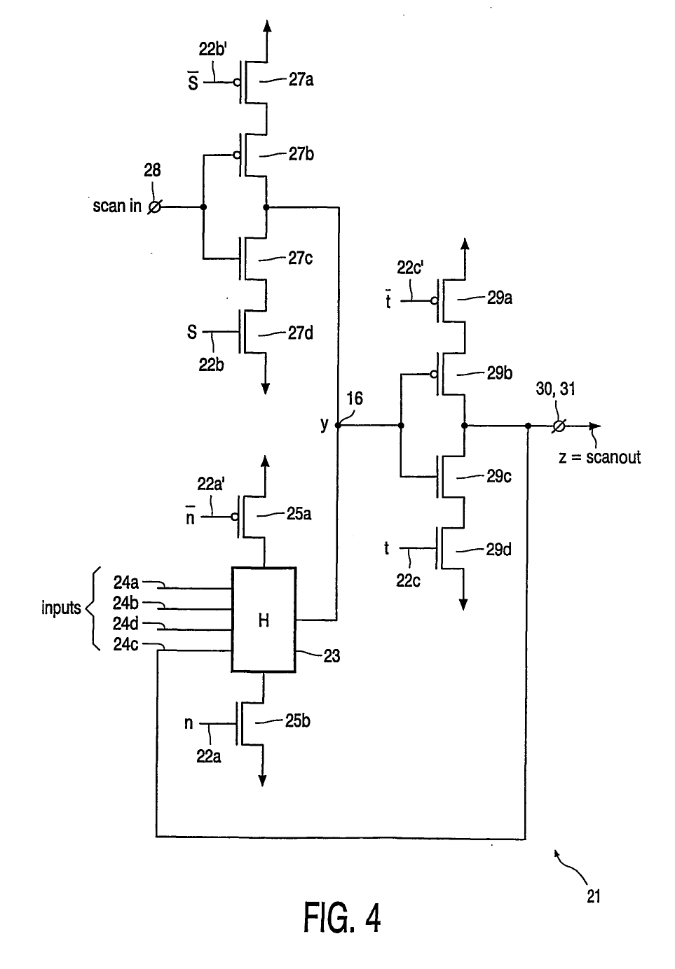

FIG. 4 shows a first implementation of a unit as shown in FIG. 3,

FIG. 5 shows a third implementation of the unit of FIG. 3,

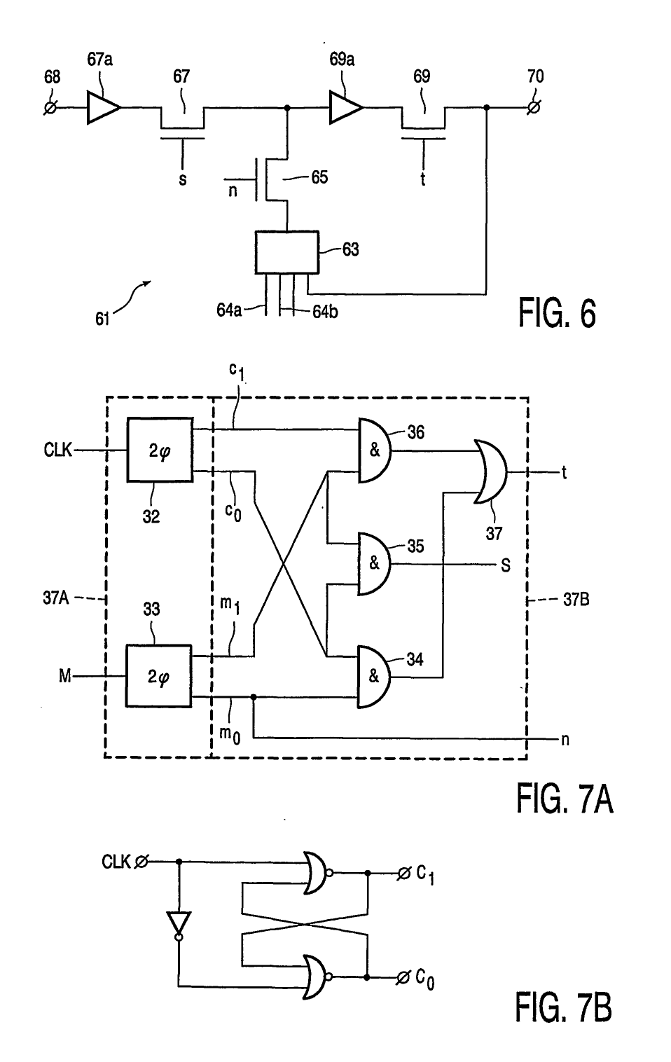

FIG. 6 shows a fourth implementation of the unit of FIG. 3,

FIG. 7A shows a decoding unit for a second implementation of the unit according to FIG. 3,

FIG. 7B shows a detail of the decoding unit of FIG. 7A,

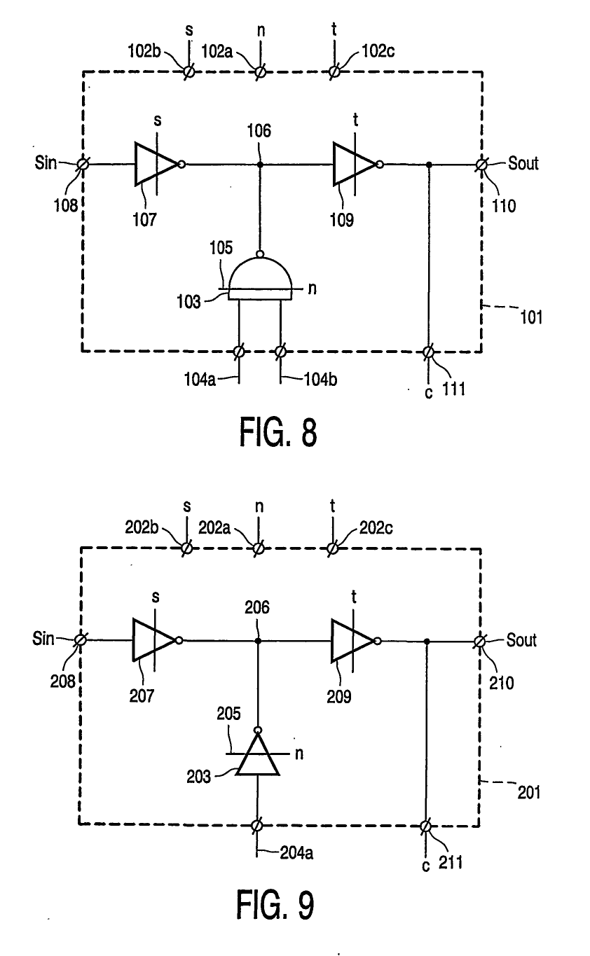

FIG. 8 shows a first example of a logical circuit in the unit of FIG. 3,

FIG. 9 shows a second example of a logical circuit in the unit of FIG. 3,

FIG. 10 shows a third example of a logical circuit in the unit of FIG. 3,

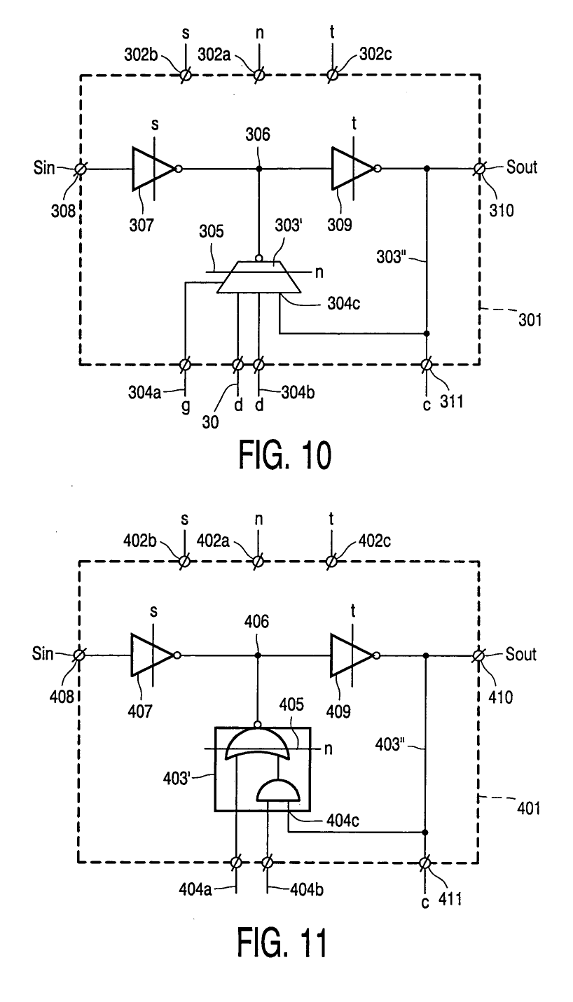

FIG. 11 shows a fourth example of a logical circuit in the unit of FIG. 3,

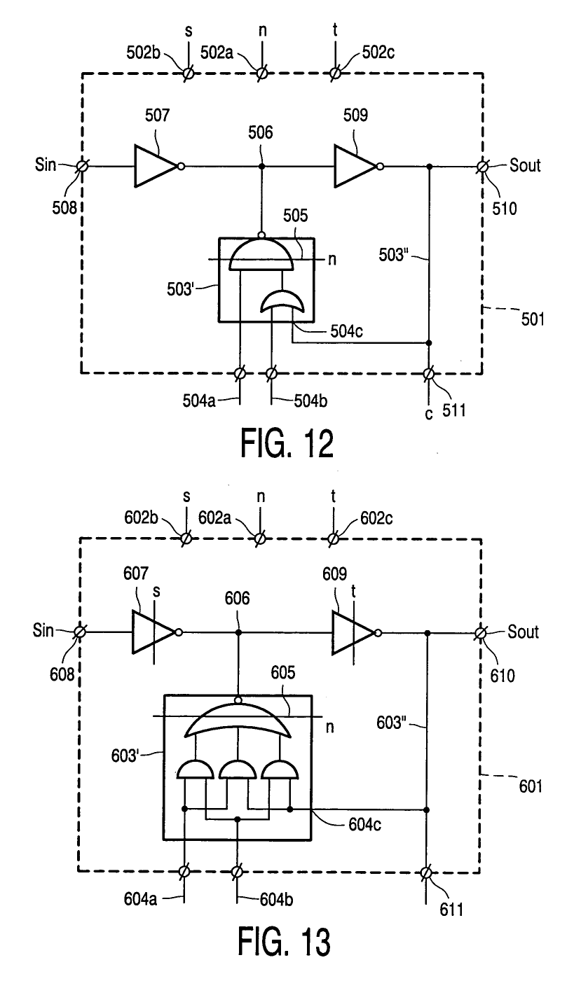

FIG. 12 shows a fifth example of a logical circuit in the unit of FIG. 3,

FIG. 13 shows a sixth example of a logical circuit in the unit of FIG. 3,

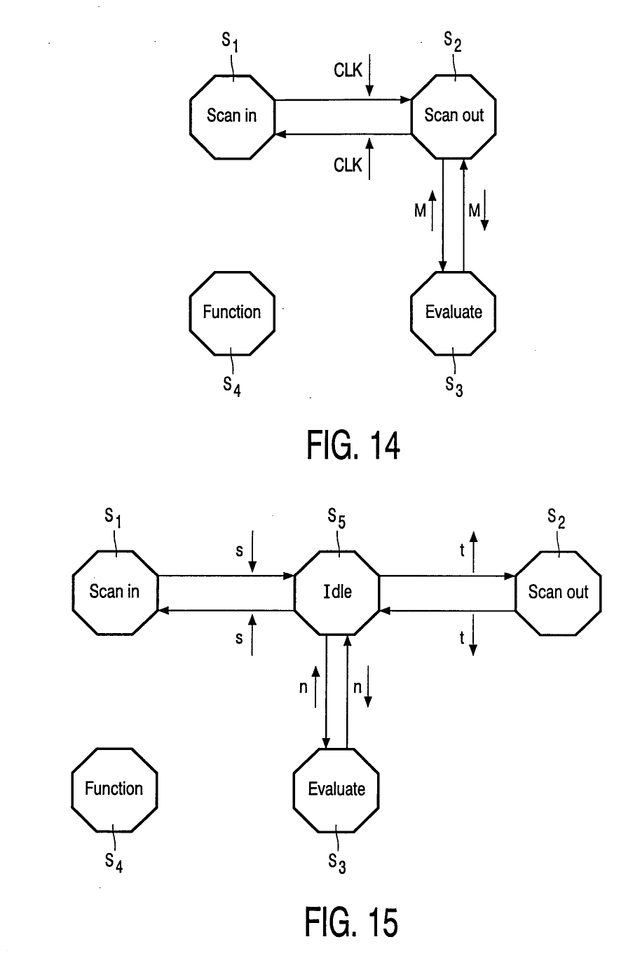

FIG. 14 shows a first method according to the invention,

FIG. 15 shows a second method according to the invention,

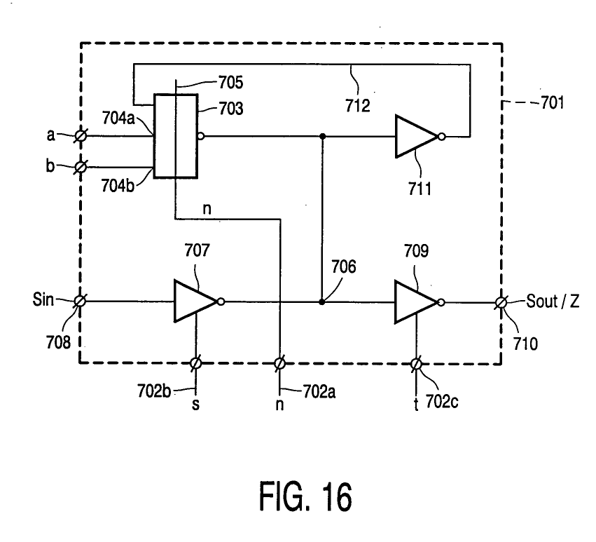

FIG. 16 shows a further example of an integrated unit according to the invention.

FIG. 3 shows a unit 1 of an integrated circuit according to the invention. The unit 1 has first inputs 2a, 2b, 2c for receiving control signals n,s,t respectively for setting an operational mode of the unit 1. It further has a logic circuitry 3 for performing a logical operation at the signals a, b received at second inputs 4a, 4b. The unit comprises first tristate means 5 for coupling an output of the logic circuitry 3 to an internal node 6 in dependence of a first control signal n. The logic circuitry 3 and the tristate means 5 act as first tristate buffering means. It has second tristate buffering means 7 for coupling a scan input 8 to the internal node 6 in dependence of a second control signal s, and third tristate buffering means 9 for coupling the internal node 6 to an output 10 of the unit 1, in dependence of a third control signal t. The output 10 functions as a scan output, for providing the scan out signal Sout. In the embodiment shown it is directly coupled to a further output 11 for providing a functional output signal c.

The unit 1 assumes a functional mode when the control signals n,s,t are set at a value 1,0,1 respectively. In the functional mode the tristate buffering means 5 and 9 are enabled. This has the result that a logical operation is performed by the logic circuitry 3 at the signal a, b received at its inputs. In the embodiment of FIG. 3 the logic circuitry 3, in combination with the tristate buffering means 5, 9 functions as a sequential element, as the output value of the logic circuitry 3, made available to the internal node 6 is fed back via the tristate buffering means 9 to the further input 4c of the logic circuitry. This allows for a static storage in the functional mode.

In an integrated circuit comprising a chain of units 1 according to the invention, a test vector can be loaded in the chain by alternatively setting the chain in a scan in mode and a scan out mode. Both in the scan in mode and in the scan out mode the first tristate buffer means 5 for coupling the logic circuitry 3 to the internal node 6 is disabled. In the scan in mode the second tristate buffer means 7 is enabled, and the third tristate buffer means 9 is disabled so that a value at the scan input 8 is dynamically stored at the internal node 6. In the scan out mode the second tristate buffer means 7 is disabled, while the third tristate buffer means 9 is enabled. In this mode the value at the internal node 6 is provided to the output 10 and dynamically stored there. By alternately switching between scan in and scan out mode a test vector can be loaded in the scan chain, or a response loaded in the scan chain can be read out from the scan chain.

The integrated circuit according to the invention further has an evaluate mode. In the evaluate mode only the first tristate buffer means 5 is enabled, the second and the third tristate buffer means 7, 9 are disabled. In the evaluate mode the result of the logical operation at the input signals a, b is dynamically stored at the internal node 6. The result of the evaluation also depends on the current state of Sout, which allows testing of the feedback from output 10 to input 4c. The tristate buffer means 5, 7, 9 achieve that signal transmission can only take place in one direction, i.e. from the input 8 to the internal node 6 and from the internal node 6 to the output 8, and not the other way around. The logic circuitry 3 usually acts as a buffer.

The tristate buffer means 5, 7 and 9 can be implemented in various ways.

FIG. 4 shows an embodiment in which the tristate buffer means are tristate inverting buffers. In FIG. 4, elements corresponding to those of FIG. 3 have a reference number which is 20 higher. The unit is controlled by six control signals n, \overline{n}, s, \overline{s}, t and \overline{t}. The first tristate buffer means comprise a first switchable semiconductor element 25a which couples the logic circuitry 23 to the positive rail and a second switchable semiconductor element 25b which couples the logic circuitry 23 to the negative rail. The first tristate buffer means 25a, 25b is enabled if the control signal n has a value 1 and the control signal \overline{n} has a value 0. The first tristate buffer means 25a, 25b is disabled if the control signal \overline{n} has a value 0 and the control signal \overline{n} has a value 1. The second tristate buffer means is implemented by a third, a fourth, a fifth and a sixt switchable semiconductor element 27a, 27b, 27c, 27d which are connected in series. This tristate buffer means 27a, . . . , 27d is enabled if the control signal s and \overline{s} respectively have a value 1 and 0. In the enabled state the tristate buffer means 27a, . . . , 27d operates as an inverting buffer. It is disabled if the control signal s and \overline{s} respectively have a value 0 and 1. The implementation of the third tristate buffer means 29a, . . . , 29d is analogous to that of the second tristate buffer means. It is enabled by the control signals t and \overline{t} having a value 1 and 0 respectively and disabled when these signals t and \overline{t} having a value 0 and 1 respectively.

In other embodiments the tristate buffer means may be implemented by a combination of a transmission gate and a buffering element. FIG. 5 shows a unit 41 in an integrated circuit according to the invention. Therein the logic circuit 45 in combination with the transmission gate 43 serves as first tristate buffer means. The second tristate buffer means are formed by the combination of inverting buffer 47a and the transmission gate 47. The third tristate buffer means are formed by the combination of the inverting buffer 49a and the transmission gate 49. In FIG. 5 parts corresponding to those of FIG. 3 have a reference numeral which is 40 higher.

A logic stage in CMOS is inverting. Since CMOS is the technology of choice today, the preferred embodiments of FIG. 3, 4, and 5 include inverting stages as symbolically indicated. Naturally, it is also possible to use non-inverting stages. An implementation of this, in combination with the use of pass gates 67a, 69a as tri-state elements, is shown in FIG. 6. Elements therein corresponding to those of FIG. 3 have a reference number which is 60 higher. Also several tristate buffer means of different kinds may be used within one unit.

Although in the embodiment shown in FIG. 4 the unit 21 is controlled by the six control signals n, \overline{n}, s, \overline{s}, t and \overline{t}, it could be alternatively controlled by three control signals n,s,t, the signals \overline{n}, \overline{s}, \overline{t} being obtained by inverting the control signals n,s,t in the unit 21. This reduces the number of connections to the unit.

FIG. 14 schematically shows a method for testing the integrated circuit of the invention According to this method, the integrated circuit is set into scan in mode S1, and subsequently set into scan out mode S2. These steps are repeated for a plurality of times, so that a testvector can be loaded in the chain formed by the units 1 according to the invention. With this repetition of steps the elements of the testvector are loaded subsequently into the internal node 6 of a unit 1, into the node formed by output 10 of that unit and input 8 of the next unit, to internal node 6 of the next unit 6 etc. Next, the integrated circuit is set into an evaluation mode S3, wherein the response to the test vector loaded in the chain of units 1 is evaluated. After this evaluation mode the response to the testvector can be retrieved from the chain of units 1, by again repeatedly alternating between scan in mode S1 and scan out mode

S2. Apart from scan in mode, scan out mode, evaluate mode the integrated circuit according to the invention has its functional mode S4. These four modes can be encoded by two control signals a clocksignal Clk and a mode signal M as shown in the following table.

| Mode | Clk | M |
|---|---|---|
| S1: scan in | 1 | 0 |
| S2: scan out | 0 | 0 |
| S3: evaluate | 0 | 1 |
| S4: functional | 1 | 1 |

In some cases it may occur that information of the testvector or the response thereto is lost if the scan in mode S1 is immediately followed by a scan out mode S2 and vice versa. A preferred embodiment of the method according to the invention is applied to an integrated circuit according to the invention, which further has an idle mode S5. In this mode the first 5, the second 7 and the third 9 tristate buffer means are each disabled, i.e. in their tristate mode. In said embodiment of the invention each step of setting the integrated circuit in a scan in mode S1, a scan out mode S2, or an evaluation mode S3 is preceded by setting the integrated circuit in the idle mode S5. This is schematically shown in FIG. 15. The following table shows the control signals n, s and t required for each of these modes, including the functional mode.

| Mode | n | s | t |
|---|---|---|---|
| S1: scan in | 0 | 1 | 0 |
| S2: scan out | 0 | 0 | 1 |
| S3: evaluate | 1 | 0 | 0 |
| S4: functional | 1 | 0 | 1 |
| S5: idle | 0 | 0 | 0 |

Although three control signals are required to control the three tristate gates in a unit of the integrated circuit of the invention, it is desirable to set the different states by as less control lines as possible so as to keep the number of pins low and to save on chip area.

For this purpose the integrated circuit is preferably chracterized by decoder logic for decoding a first Clk and a second input control signal M into the first n, the second s and the third control signal t. Such decoder logic can for example be present once, close to input pins for the input control signals, but can alternatively be present in each unit of the integrated circuit. Otherwise the integrated circuit can have groups of units which each have such a decoder. An example of a preferred embodiment of such decoder logic is shown in FIG. 7A.

The decoder logic shown therein comprises a first stage 37A including a first and a second two-phase circuit 32, 33. The first two phase circuit 32 converts the input control signal Clk in a first and a second output clock signal c0 and c1. The two-phase circuit, which is known as such, is shown in more detail in FIG. 7B. The first two-phase circuit 32 generates an output clock signal c0, and an inverse output clock signal c1, wherein alternately one of the clocksignals has a first logic value, the clock signals both having a second opposite logical value between each alternation from a state where one of the clock signals has the first logical value to a state where the other of the clock signal has the first logical value.

The second two-phase circuit 33 converting the input control signal M in an output mode signal m0 and an inverse output mode signal m1 in a way analogous as the first two-phase circuit. In the second stage 37B the control signals s,n,t are computed from the signals c0, c1, m0, m1.

The control signal n is identical to the output mode signal m0.

The control signals s and t are calculated by means of AND-gates 34, 35 and 35, and the OR-gate 37 as follows.

s=c0 AND m1

t=(c1 AND m1) OR (c0 AND m0)

| Clk | M | c0 | c1 | m0 | m1 | n | s | t | Mode |
|---|---|---|---|---|---|---|---|---|---|
| 1 | 0 | 1 | 0 | 0 | 1 | 0 | 1 | 0 | S1: scan in |
| 0 <> 1 | 0 | 0 | 0 | 0 | 1 | 0 | 0 | 0 | S5: idle |
| 0 | 0 | 0 | 1 | 0 | 1 | 0 | 0 | 1 | S2: scan out |
| 0 | 0 <> 1 | 0 | 1 | 0 | 0 | 0 | 0 | 0 | S5: idle |
| 0 | 1 | 0 | 1 | 1 | 0 | 1 | 0 | 0 | S3: evaluate |
| 1 | 1 | 1 | 0 | 1 | 0 | 1 | 0 | 1 | S4: functional |

In the above table it is seen that during a time interval after a transition of the signal C1 from 0 to 1 or from 1 to 0, indicated by 0< >1, both output signals of the two phase circuit are a logical 0. This implies that each of the control signals n, s, t is a logical 0 so that the integrated circuit always has the idle state, as an intermediate state between the scan in state and the scan out state. In the same way it is ascertained that the integrated circuit assumes the idle state when it passes from the scan out state to the evaluate state. Yet, only two control signals are required to achieve this.

FIGS. 8 to 13 show some examples of units in an integrated circuit according to the invention. By way of example the first, second and third tristate buffer means are implemented as an inverting tristate buffer and schematically indicated by means of the bar(−) and the inverting sign (o).

In the example shown in FIG. 8 parts corresponding to those of FIG. 3 have a reference number which is 100 higher. The logic circuit 103 in this embodiment is an AND-gate.

In the example shown in FIG. 9 parts corresponding to those of FIG. 3 have a reference number which is 200 higher. The logic circuit 203 in this embodiment has an output which is only dependent on a single input 204a. In the embodiment shown it is a connection 203, but it could otherwise be an inverter or a delay element.

FIG. 3, 4, and 6 illustrate how a ring consisting of two logic stages, i.e. 3 and 9 can be incorporated in a scan chain. This is also possible for rings consisting of more than two stages, even for rings consisting of an odd number of stages. For instance, a ring oscillator consisting of three logic stages can be constructed from FIG. 9 by adding an invertor between output 211c and input 204a.

In the example shown in FIG. 10 parts corresponding to those of FIG. 3 have a reference number which is 300 higher. The logic circuit 303′ therein is a multiplexing unit. The multiplexing unit 303′ has as second inputs signal inputs 304b and 304c, and a selection input 304a for selecting between signal input 304b and 304c. The signal input 304c of the multiplexing unit 303′ is coupled via a feedback 303″ to the output of the multiplexing unit. The multiplexing unit 303′ and the feedback 303″ together form a latch. Its implementation in a unit 301 according to the circuit of the invention allows the latch 303′, 303″ to be tested easily, including the feedback 303″.

In the examples shown in FIG. 11 and FIG. 12 parts corresponding to those of FIG. 3 have a reference number which is 400 higher and 500 higher respectively. FIG. 11 and FIG. 12 both show an example in which the logic element 403′, 404′ in combination with the third tristate buffer means 409, 509 and a feedback 403″, 503″ from the output 410, 510 of the triastate means to one of the inputs 404c, 504c of the logic circuitry 403′, 503′ is an asymmetric C-element. Also its implementation in a unit 401 and 501 respectively according to the circuit of the invention allows the asymetric C-elements 403′+409+403″ and 503′+509+503″ to be tested easily.

In the example shown in FIG. 13, parts corresponding to those of FIG. 3 have a reference number which is 600 higher. FIG. 13 shows an example in which the logic element 603′ in combination with the third tristate buffer means 609 and a feedback 603″ from the output 610 of the third tristate buffer means 609 to one the inputs 604c of the logic circuitry 603′is a symmetric C-element. Its implementation in a unit 601 according to the circuit of the invention allows the symetric C-elements 603′+603″ to be tested easily.

In the example shown in FIG. 16, parts corresponding to those of FIG. 3 have a reference number which is 700 higher. In the unit shown therein the internal node 706 is coupled to an input 704c of the logic circuitry 703 via a path comprising a buffer 711 and a connection 712. This path is separate from the path from the internal node 706 to the output 710. This embodiment has the advantage that the feedback of the internal node 706 is fully decoupled from the output 710. This makes it attractive as a standard cell.

1. Integrated circuit comprising a plurality of units (C 1, C2, C3, C4;1), having first inputs (2a, 2b, 2c) for receiving control signals (n,s,t) for setting an operational mode of the unit (1), the unit (1) having a functional mode, a scan in mode, a scan out mode,
in which functional mode (n=1,s=0,t=1) a logical operation is performed at signals (a,b) received at one or more second inputs (4a, 4b), the result of the logical operation being provided via an internal node (6) to an output (10), in which scan in mode (n=0,s=1,t=0) a value at a scan input is stored at the internal node (6), in which scan out mode (n=0,s=0,t=1) the value at the internal node (6) is provided to the output (10),
characterized in that the integrated circuit further has an evaluate mode (n=1,s=0,t=0) in which the result of the logical operation at the input signals (a,b) is stored at the internal node (6), and in which the output (10) of the units is disabled.

2. Integrated circuit according to claim 1, characterized in that the units (1) have a logic circuit (3) for performing a logical operation at the signals (a,b) received at the second inputs (4a, 4b), the logic circuit including first buffering tristate buffer means (5) for coupling an output of the logic circuitry (3) to the internal node (6) in dependence of a first control signal (n), second buffering tristate means (7) for coupling the scan input (8) to the internal node (6) in dependence of a second control signal (s), third buffering tristate means (9) for coupling the internal node (6) to the output (10), in dependence of a third control signal (t).

3. Integrated circuit according to claim 2, characterized in that an output (10) of the third buffering tristate means (9) is coupled to an input (4c) of the logic circuitry (3).

4. Integrated circuit according to claim 2, characterised by decoder logic (32) for decoding a first (Clk) and a second input control signal (M) into the first (n), the second (s) and the third control signal (t).

5. Integrated circuit according to claim 4, characterized in that the decoder logic comprises a first stage (37A) including a first and a second two-phase circuit (32, 33), the first two phase circuit (32) converting the first input control signal (Clk) in an output clock signal (c0), and an inverse output clock signal (c1), wherein alternately one of the clocksignals has a first logic value, the clock signals both having a second opposite logical value during each transition from a state where one of the clock signals has the first logical value to a state where the other of the clock signal has the first logical value, the second two-phase circuit (33) converting the second input control signal (M) in an output mode signal (m0) and an inverse output mode signal (m1), the clock signals both having a second opposite logical value during each transition from a state where one of the clock signals has the first logical value to a state where the other of the clock signal has the first logical value, the decoder logic further comprising a second stage (37B) in which the first, the second and the third control signals (s,n,t) are computed from the output clock signal (c0), the inverse output clock signal (c1), the output mode signal (m0) and the inverse output mode signal (m1).

6. Integrated circuit according to claim 2, characterized in that the logic circuit has an output which is only dependent on a single input.

7. Integrated circuit according to claim 2, characterized in that the logic circuit is an AND-gate.

8. Integrated circuit according to claim 3, characterized in that the logic circuit (303′) in combination with the third buffering tristate means (309) and a feedback (303″) coupling an output (310) of the third buffering tristate means (309) to an input (304c) of the logic circuitry (303′) forms a latch.

9. Integrated circuit according to claim 3, characterized in that the logic circuit (403′;503′) in combination with the third buffering tristate means (409;509) and a feedback (403″;503″) coupling an output (410;510) of the third buffering tristate means (409;509) to an input (404c;504c) of the logic circuitry (403′;503′) forms an asymmetric C-element.

10. Integrated circuit according to claim 3, characterized in that the logic circuit (603′) in combination with the third buffering tristate means (609) and a feedback (603″) coupling an output (610) of the third buffering tristate means (609) to an input (604c) of the logic circuitry (603′) forms a symmetric C-element.

11. Integrated circuit according to any of the claim 1, characterized by an idle mode wherein the first (5), the second (7) and the third buffering tristate means (9) each are disabled.

12. Integrated circuit according to claim 2, characterized in that the internal node (706) is coupled to an input (704c) of the logic circuitry (703) via a path (711, 712) which is separate from the path from the internal node (706) to the output (710).

13. Method for testing an integrated circuit according to one of the claim 1, characterized in that the method comprises
a. setting the integrated circuit in scan in mode (S1),
b. setting the integrated circuit in scan out mode (S2),
c. repeating steps a to b for a plurality of times
d. setting the integrated circuit in an evaluation mode (S3),
e. repeating steps a to b for a plurality of times.

14. Method according to claim 13 for testing an integrated circuit according to claim 10, characterized in that each step of setting the integrated circuit in a scan in mode (S1), a scan out mode (S2), or an evaluation mode (S3) is preceded by setting the integrated circuit in the idle mode (S5).
